(19) United States
(12) Patent Application Publication
(10) Pub. No.: US 2012/0228713 A1
(43) Pub. Date: Sep. 13, 2012

(54) THREE-DIMENSIONAL COMPLEMENTARY METAL OXIDE SEMICONDUCTOR DEVICE

(76) Inventors: Kuan-Neng Chen, Hsinchu City (TW); Yao-Jen Chang, Taipei City (TW)

(21) Appl. No.: 13/155,679

(22) Filed: Jun. 8, 2011

(30) Foreign Application Priority Data
Mar. 11, 2011 (TW) 100108298

(51) Int. Cl. H01L 27/092

(52) U.S. Cl. 257/369; 257/E27.062

(57) ABSTRACT

A three-dimensional complementary metal oxide semiconductor device comprises a bottom wafer having a first-type strained MOS transistor; a top wafer stacked on the bottom wafer face to face or face to back, having a second-type strained MOS transistor arranged opposite to the first-type strained MOS transistor, and having a plurality of metal pads and a plurality of TSVs connected to the metal pads; and a hybrid bonding layer arranged between the bottom wafer and the top wafer, having metallic-bonding areas connecting the first-type and second-type MOS transistors to TSVs and a non-metallic bonding area filled in all space except the metallic bonding areas, so as to bond the bottom and top wafers.

### BACKGROUND OF THE INVENTION

1. Field of the Invention

The present invention relates to a 3D CMOS device, particularly to a 3D CMOS device fabricated with a face-to-face or face-to-back hybrid bonding technology.

2. Description of the Related Art

In order to realize fast-operation CMOS (Complementary Metal Oxide Semiconductor) IC should be decreased the switching time of transistors and the transmission delay of the interconnections. Decreasing the switching time can be achieved by decreasing the interconnection length of transistors and increasing the carrier mobility of semiconductor. Difference of lattice constants or crystallographic directions can be used to strain a semiconductor material and modify the carrier mobility of thereof.

For example, a U.S. Pat. No. 7,763,915 disclosed three embodiments using hybrid substrates to construct fast-operation CMOS IC. In a first embodiment thereof, a germanium silicide layer is formed on a substrate with a chemical vapor deposition method, and a monocrystalline silicon layer is formed on the germanium silicide layer with an epitaxial method. A PMOS (P-type Metal Oxide Semiconductor) transistor is formed on the germanium silicide layer, and an NMOS (N-type Metal Oxide Semiconductor) transistor is formed on the monocrystalline silicon layer. An interconnection is formed between the PMOS and the NMOS. Such a scheme has the following drawbacks: 1. The dopant of the PMOS transistor or the NMOS transistor is likely to diffuse into the other layer, and thermal budget is likely to accumulate persistently during the fabrication process. 2. As there is a germanium silicide layer existing below the NMOS transistor, leakage current is likely to occur in the underneath. 3. The throughput is low. 4. Multilevel deposited layers are likely to relax strain.

In a second embodiment thereof, a (100) region and a (110) region are formed in a substrate via layer transformation in an SOI (silicon on insulator) wafer and a smart-cut joining technology; a PMOS transistor and an NMOS transistor are respectively formed on the (100) region and the (110) region. However, such a scheme also has low throughput and accumulated thermal budget.

In a third embodiment thereof, local elastic deformations are used to achieve the objective. For example, a PMOS transistor and an NMOS transistor are respectively formed in a tensile-stress area and a compressive-stress area of an identical material. Such a scheme has less flexibility because the PMOS transistor and the NMOS transistor adopt an identical material.

Accordingly, the present invention proposes a novel 3D CMOS device to overcome the abovementioned problems.

### SUMMARY OF THE INVENTION

The primary objective of the present invention is to provide a 3D CMOS device, wherein device area is greatly reduced, and wherein the interconnections, between PMOS and NMOS is obviously shortened, whereby the operation speed is increased.

Another objective of the present invention is to provide a 3D CMOS device, wherein the PMOS and the NMOS are first fabricated respectively, whereby thermal budget is decreased, and whereby the cost for integrating the fabrication processes is reduced, and whereby the fabrication of the strained layers of the substrate is simplified.

A still another objective of the present invention is to provide a 3D CMOS device, wherein different wafer materials, different wafer orientations, or different fabrication processes are used to vary strain and improve carrier mobility.

A yet another objective of the present invention is to provide a 3D CMOS device, wherein the fabrication of the CMOS thereof is exempted from well doping and adapted to the apparatuses of the common semiconductor processes, whereby the fabrication cost thereof is effectively reduced.

A further objective of the present invention is to provide a 3D CMOS device, which is a hybrid structure formed by stacking two wafers, wherein different substrates, such as substrates made of silicon, gallium arsenide, quartz, germanium or carbon silicide, are stacked together to integrate optoelectronic, electronic and microelectronic components.

To achieve the abovementioned objectives, the present invention proposes a 3D CMOS device, which comprises a bottom wafer having a first-type strained MOS; a top wafer stacked on the bottom wafer face-to-face or face-to-back and having several metal pads, several TSVs (Through Silicon Vias) connected with the metal pads, and a second-type strained MOS arranged opposite to the first-type MOS; and a hybrid bonding layer arranged between the bottom wafer and the top wafer and having metallic bonding areas electrically connecting the first-type MOS and the second-type MOS to TSVs and a non-metallic bonding area filled into all space except the metallic bonding areas to join the bottom wafer and the top wafer.

Below, the embodiments are described in detail to make easily understood the objectives, technical contents, characteristics and accomplishments of the present invention.

### BRIEF DESCRIPTION OF THE DRAWINGS

FIG. 1A is a perspective view schematically showing a 3D CMOS device according to one embodiment of the present invention;

FIG. 1B is a sectional view schematically showing a 3D CMOS device according to one embodiment of the present invention; and

FIGS. 2A-2E are perspective views schematically showing steps of fabricating a 3D CMOS device according to one embodiment of the present invention.

### DETAILED DESCRIPTION OF THE INVENTION

Below, embodiments are used to demonstrate the technical contents of the present invention. However, these embodiments are not intended to limit the scope of the present invention but only to exemplify the present invention.

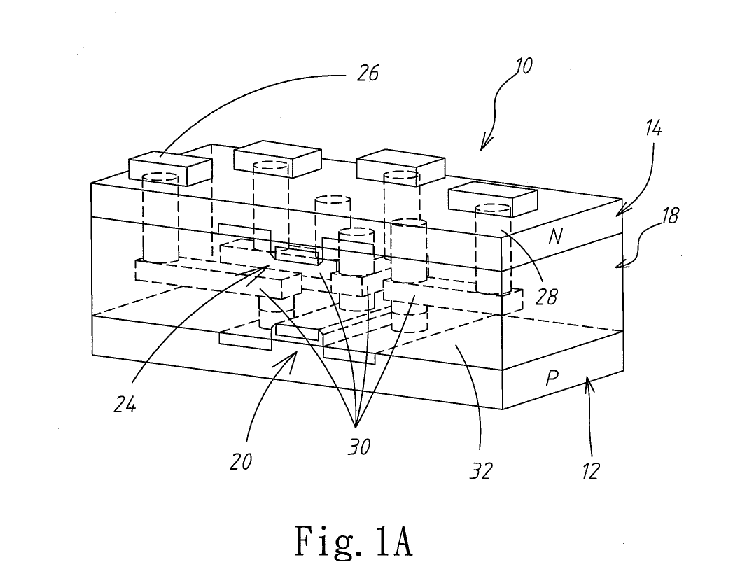

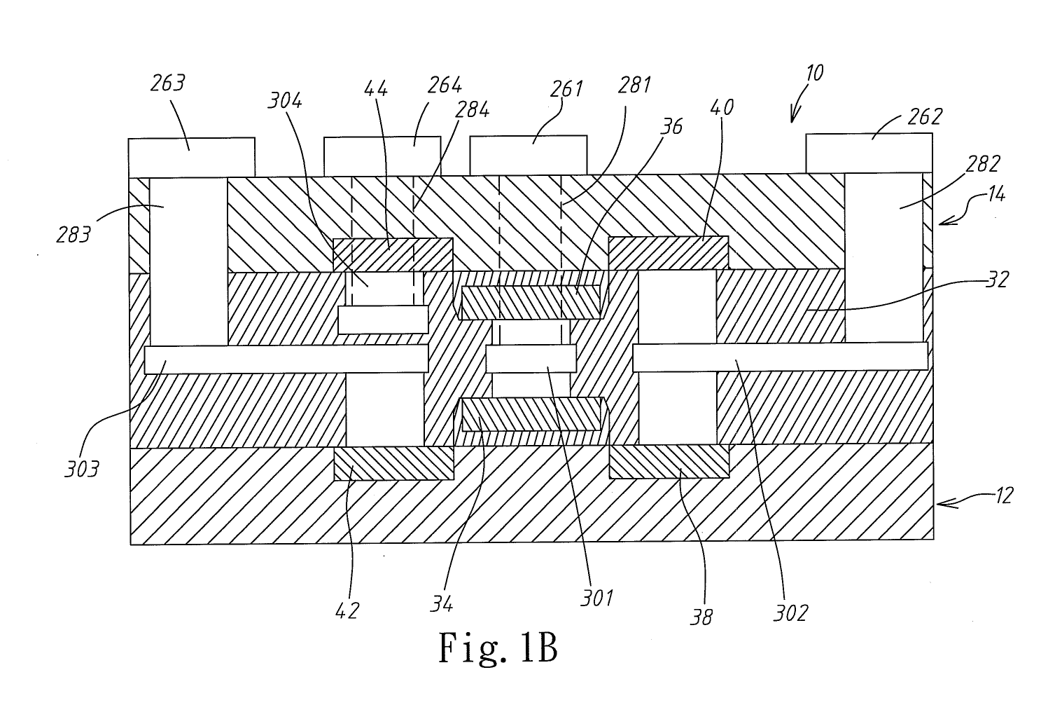

Refer to FIGS. 1A and 1B respectively a perspective view and a sectional view of a high-performance 3D CMOS device according to one embodiment of the present invention. The 3D CMOS device 10 of the present invention comprises a P-type bottom wafer 12 having an axial direction of (100), an N-type top wafer 14 having an axial direction of (110), and a hybrid bonding layer 18 arranged between the bottom wafer 12 and the top wafer 14. The hybrid bonding layer 18 can be fabricated with a deposition or electroplating method.

The bottom wafer 12 has an N-type strained MOS transistor 20. The top wafer 14 has a P-type strained MOS transistor 24 arranged opposite to the N-type MOS transistor 20. The top wafer 14 also has a plurality of metal pads 26 and a plurality of TSVs (Through Silicon Vias) 28 connected with metal pads 26.

The hybrid bonding layer 18 has metallic bonding areas 30 and a non-metallic bonding area 32. The metallic bonding areas 30 electrically connect the N-type MOS device 20 and the P-type MOS device 24 to TSVs 28. The non-metallic bonding area 32 is filled into the space between the bottom wafer 12 and the top wafer 14 except the metallic bonding areas 30, to join the bottom wafer 12 and the top wafer 14. The metallic bonding areas 30 may further have dielectric layers (not shown in the drawings).

The metallic bonding areas 30 electrically connect the N-type MOS transistor 20 and the P-type MOS device 24 to TSVs 28. The metallic bonding areas 30 include metallic bonding areas 301, 302, 303 and 304. The metallic bonding area 301 electrically connects the gate 34 of the N-type MOS transistor 20 and the gate 36 of the P-type MOS transistor 24. Via TSV281, the metallic bonding area 301 is connected to the metal pad 261 functioning as an input terminal. The metallic bonding area 302 electrically connects the drain 38 of the N-type MOS transistor 20 and the drain 40 of the P-type MOS transistor 24. Via TSV282, the metallic bonding area 302 is connected to the metal pad 262 functioning as an input terminal. The metallic bonding area 303 electrically connects with the source 42 of the N-type MOS transistor 20. Via TSV283, the metallic bonding area 303 is connected to the metal pad 263. The metallic bonding area 304 electrically connects with the source 44 of the P-type MOS transistor 24. Via TSV284, the metallic bonding area 304 is connected to the metal pad 264.

In one embodiment, the bottom wafer 12 further has a tensile strain layer, and the top wafer 14 further has a compressive strain layer, whereby is increased the carrier mobility of the MOS transistors. The top wafer 14 is made of silicon, gallium arsenide, quartz, germanium, or carbon silicide. The bottom wafer 12 is made of silicon, gallium arsenide, quartz, germanium, or carbon silicide. The top wafer 12 and the bottom wafer 14 may be respectively made of different materials to form a heterogeneous device integrating optoelectronic, electronic and microelectronic components. The gate 34 of the N-type MOS transistor 20 and the gate 36 of the P-type MOS transistor 24 may be made of high permittivity metallic materials.

The metallic bonding areas 30 of the hybrid bonding layer 18 is made of tin, silver or copper. The non-metallic bonding area 32 is made of a resin material, such as BCB (benzocyclobutene), SU8, a polymer or PI (polyimide). Alternatively, the non-metallic bonding area 32 is made of a non-resin material, such as a deposited silicide, which can bind the top wafer 14 to the bottom wafer 12 with Van der Waals force.

In the present invention, the gates of the N-type MOS transistor and the P-type MOS transistor are vertically and closely arranged and electrically connected; the source of the P-type MOS transistor and the drain of the N-type MOS transistor are also closely arranged and electrically connected. Thereby is reduced the transmission delay of interconnections and achieved a fast-operation CMOS IC.

In the present invention, the MOS transistors of a CMOS device are stacked vertically face-to-face or face-to-back. As the CMOS device of the present invention occupies only a half of area of the conventional CMOS device whose MOS transistors are arranged coplanarly, the interconnection length of the CMOS device of the present invention is greatly reduced.

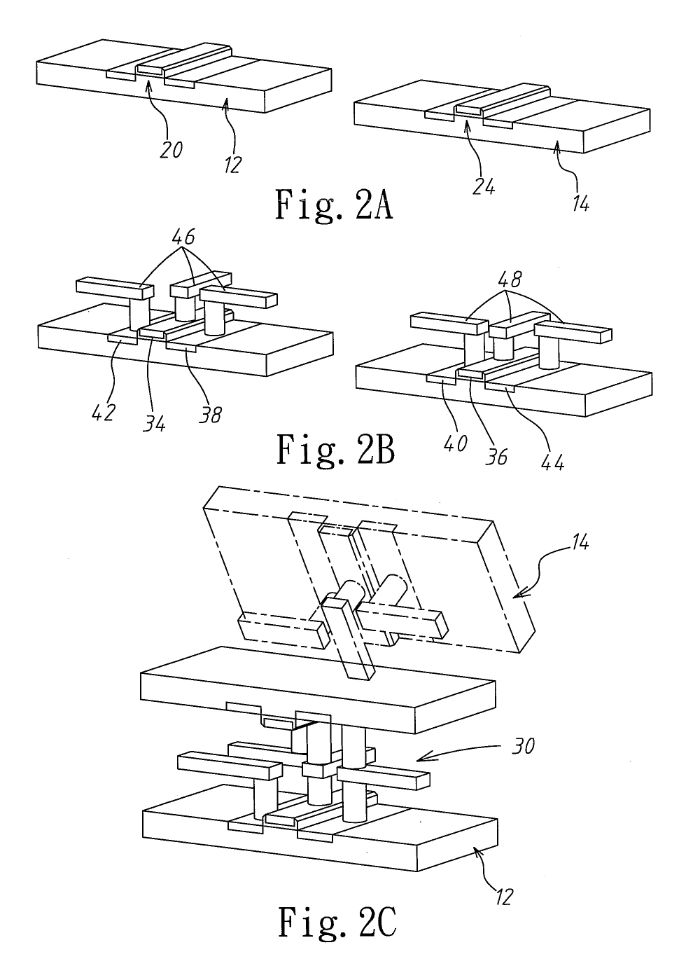

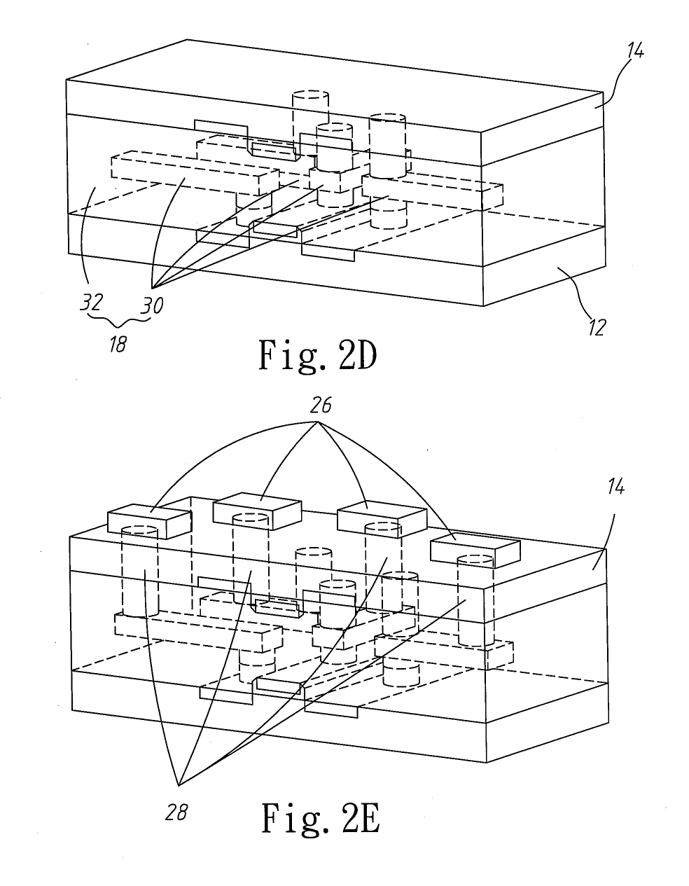

Refer to FIGS. 2A-2E for steps of fabricating a 3D CMOS device according to one embodiment of the present invention. Since the technical contents of the individual elements have been described above, they will not repeat below.

As shown in FIG. 2A, provide a P-type bottom wafer 12 having an axial direction of (100), and form an N-type strained MOS transistor 20 on the bottom wafer 12; provide an N-type top wafer 14 having an axial direction of (110), and form a P-type strained MOS transistor 24 on the top wafer 14.

Next, as shown in FIG. 2B, form sub-metallic bonding areas 46 respectively connected with the gate 34, source 42 and drain 38 of the N-type MOS transistor 20; forming sub-metallic bonding areas 48 respectively connected with the gate 36, source 40 and drain 44 of the P-type MOS transistor 24.

Next, as shown in FIG. 2C, stack the top wafer 14 over the bottom wafer 12 face-to-face, and arrange the N-type MOS transistor 20 opposite to the P-type MOS transistor 24 to make the sub-metallic bonding areas 46 coincide and connect with the sub-metallic bonding areas 48 so as to form metallic bonding areas 30.

Next, as shown in FIG. 2D, fill or deposit a non-metallic material into the space between the top wafer 14 and the bottom wafer 12 except the space occupied by the metallic bonding areas 30 to form a non-metallic bonding area 32 to connect the top wafer 14 and the bottom wafer 12. The connection of the sub-metallic bonding areas 46 and 48 is undertaken at a temperature of 300-450° C. and under a pressure of 8-13 N/cm² for 30 minutes to 1 hour. The temperature and pressure may vary with the sizes or materials of the substrates.

Next, as shown in FIG. 2E, form TSVs 28 and metal pads 26 on the top wafer 14, wherein TSVs 28 are connected to the metallic bonding areas 30 to implement input terminals and output terminals.

In conclusion, the P-type MOS transistor and the N-type MOS transistor are fabricated separately in the present invention, whereby is decreased the thermal budget, and whereby is simplified the fabrication of the strained layers of the bottom wafer and the top wafer. For example, different materials of wafers, different axial directions of wafers or different fabrication processes may be used to generate strain in the present invention. In the present invention, the fabrication of the CMOS device is exempted from well doping and adapted to the apparatuses of the common semiconductor processes, whereby the fabrication cost is effectively reduced. In the present invention, the CMOS device is fabricated via stacking two wafers, wherefore wafers made of different materials can be stacked together to form a hybrid CMOS device integrating optoelectronic, electronic and microelectronic components.

The embodiments described above are only to exemplify the present invention but not to limit the scope of the present invention. Any equivalent modification or variation according to the spirit of the present invention is to be also included within the scope of the present invention.

What is claimed is:

1. A three-dimensional complementary metal oxide semiconductor device comprising
a bottom wafer having a first-type strained metal oxide semiconductor (MOS) transistor;
a top wafer stacked over said bottom wafer face-to-face or face-to-back, having a second-type strained MOS transistor arranged opposite to said first-type strained MOS transistor, and having a plurality of metal pads and a plurality of through-silicon vias (TSV) connected with said metal pads; and
a hybrid bonding layer arranged between said bottom wafer and said top wafer and having a plurality of metallic bonding areas and a non-metallic bonding area, wherein said metallic bonding areas electrically connect said first-type strained MOS transistor and said second-type strained MOS transistor to said TSVs, and wherein said non-metallic bonding area is filled into a space between said top wafer and said bottom wafer except said metallic bonding areas to connect said top wafer and said bottom wafer.

2. The three-dimensional complementary metal oxide semiconductor device according to claim 1, wherein said top wafer is made of a first-type semiconductor, and wherein said bottom wafer is made of a second-type semiconductor, and wherein said first-type is N-type, and wherein said second-type is P-type, and wherein said bottom wafer has an axial direction of (100), and wherein said top wafer has an axial direction of (110).

3. The three-dimensional complementary metal oxide semiconductor device according to claim 1, wherein one of said metallic bonding areas connects a gate of said first-type MOS transistor with a gate of said second-type MOS transistor, and wherein one of said metallic bonding areas connects a drain of said first-type MOS transistor with a drain of said second-type MOS transistor.

4. The three-dimensional complementary metal oxide semiconductor device according to claim 1, wherein said bottom wafer is made of silicon, gallium arsenide, quartz, germanium or carbon silicide.

5. The three-dimensional complementary metal oxide semiconductor device according to claim 1, wherein said top wafer is made of silicon, gallium arsenide, quartz, germanium or carbon silicide.

6. The three-dimensional complementary metal oxide semiconductor device according to claim 1, wherein said second-type MOS transistor has a gate made of a high-permittivity metallic material.

7. The three-dimensional complementary metal oxide semiconductor device according to claim 1, wherein said first-type MOS transistor has a gate made of a high-permittivity metallic material.

8. The three-dimensional complementary metal oxide semiconductor device according to claim 1, wherein said hybrid bonding layer is a hybrid bonding layer containing a resin and a metal, and wherein said metal is tin or copper, and wherein said resin is selected from a group consisting of BCB (benzocyclobutene), SUB, a polymer or PI (polyimide).

9. The three-dimensional complementary metal oxide semiconductor device according to claim 1, wherein said hybrid bonding layer is a hybrid bonding layer containing silicide and a metal, and wherein said metal is tin, silver or copper.

10. The three-dimensional complementary metal oxide semiconductor device according to claim 1, wherein said hybrid bonding layer is formed with a deposition or electroplating method.

11. The three-dimensional complementary metal oxide semiconductor device according to claim 1, wherein when said metallic bonding areas are made of copper, a bonding process thereof is undertaken at a temperature of 300-450° C. and under a pressure of 8-1 3N/cm2 for 30 minutes to 1 hour.
